(19) United States
(12) Patent Application Publication
(10) Pub. No.: US 2016/0223634 A1
(43) Pub. Date: Aug. 4, 2016

(54) MAGNETIZATION TRANSFER CONTRAST TECHNIQUE FOR CHEMICAL EXCHANGE SATURATION TRANSFER (CEST) MRI BY LOCALIZED STEAM AND METHOD OF OERATION THEREOF

(71) Applicant: KONINKLIJKE PHILIPS N.V., Eindhoven (NL)

(72) Inventor: Baolian YANG, EINDHOVEN (NL)

(73) Assignee: Koninklijke Philips N.V.

(21) Appl. No.: 15/021,726

(22) PCT Filed: Aug. 28, 2014
(86) PCT No.: PCT/IB2014/064108

§ 371 Date: Mar. 14, 2016

Related U.S. Application Data
(60) Provisional application No. 61/878,203, filed on Sep. 16, 2013.

(51) Int. Cl. G01R 33/56; G01R 33/561; G01R 33/28; G01R 33/483

(52) U.S. Cl. CPC G01R 33/5605; G01R 33/4833; G01R 33/5617; G01R 33/288

(57) ABSTRACT

A magnetic resonance imaging (MRI) system (600), for acquiring magnetic resonance (MR) information of a volume, includes at least one controller (610) configured generate at least a portion of a stimulated echo acquisition mode (STEAM) CEST-sequence including first through third 90° radio frequency (RF) pulses, and a first pulse train situated before the first 90° RF pulse. The first pulse train has first number of pulses. The controller (610) is further configured to generate at least another portion of the STEAM CEST sequence comprising a second pulse train situated between the second and third 90° RF pulses, the second pulse train comprising a second number of pulses which is less than the first number of pulses; generating end of spoil gradients; and/or to ac quire MR information during an acquisition window which is stated at least partially after the end of spoil gradients.

Embodiments of the present disclosure relate to a magnetic resonance imaging (MRI) system which acquires image information using nuclear magnetic resonance (NMR) methods and, more particularly, to an MRI system for performing a magnetization transfer (MT) contrast technique such as a chemical exchange saturation transfer (CEST) technique, to improve magnetization contrast and a method of operation thereof.

CEST MRI is an MT contrast technique in which exogenous or endogenous compounds containing either exchangeable protons or exchangeable molecules are selectively saturated and, thereafter, detected indirectly through a water signal with enhanced sensitivity (see, R1, R2). The application of CEST MRI can be expanded into research areas such as oncology research (e.g., Amide Protons Transfer (APT) (see, R3)), ischemic heart disease research, myocardial infarction research (e.g., Creatine MT spectroscopy (see, R4)), Glycogen quantification (glycoCEST) research and/or Glutamate quantification research. Normally, a magnetization-transfer-ratio (MTR) is less than 10% (see, R1), and the measured MTR value of the CEST MRI depends on the length of a saturation pulse. Typically, CEST MRI relies upon a long (e.g., 1-2 sec) low-power (<3 μT for a body coil as an RF transmitter) frequency-offset radio-frequency (RF) pulse (or pulse train) applied before an MRI sequence is applied so as to achieve higher MT contrast than conventional images. Because of this long saturation pulse, CEST MRI typically requires a longer scan time than required by a conventional MRI sequence technique due to Specific Absorption Rate (SAR) control as required by the Food and Drug Administration (FDA) for a patient's safety. Accordingly, a typical CEST MRI technique typically requires about 10 to 20 minutes to perform depending upon a number of frequency offset scans used. Further, the sensitivity of conventional CEST MRI is also limited by non-uniform B₁ and B₀ fields. By using Stimulated Echo Acquisition Mode (STEAM) (see, R6) to select the signals only from a region-of-interest (ROI) such as a tumor, the relative uniformity of B₁ and B₀ fields is improved. Also, the additional saturation pulses inserted in a STEAM TM period can improve the MTR.

The system(s), device(s), method(s), user interface(s), computer program(s), processes, etc. (hereinafter each of which will be referred to as system or the system, unless the context indicates otherwise) described herein address problems in prior art systems.

In accordance with embodiments of the present system, there is disclosed a magnetic resonance imaging (MRI) system for acquiring magnetic resonance (MR) information of a volume, the MRI system including at least one controller which may generate at least a portion of a stimulated echo acquisition mode (STEAM) CEST sequence including first through third 90° radio frequency (RF) pulses and a first pulse train situated before the first 90° RF pulse, the first pulse train including a first number of pulses; generate at least another portion of the STEAM sequence including a second pulse train situated between the second and third 90° RF pulses, the second pulse train including a second number of pulses which is less than the first number of pulses; generate end of spoil gradients; and/or may acquire MR information during an acquisition window which is stated at least partially after the end of the spoil gradients.

It is further envisioned that the first pulse train may include between 16 and 50 pulses. Moreover, the second pulse train may include between 4 and 10 pulses. Further, at least one of the first and second pulse trains may include sin(x)/x (SINC) pulses. It is also envisioned that each of the pulses of the first and second pulse trains may be equal to each other. It is also envisioned that a ratio of a number of pulses of the first pulse train to the second pulse train may be greater than or equal to a desired value such as an integer value, such as 4, for example. It is also envisioned that the pulses of the second pulse train have the same duration, interval and shape as the first pulse train. It is further envisioned that the controller may reconstruct the acquired MR information to form at least one of corresponding image information and spectroscopy information.

In accordance with yet another aspect of the present system, there is envisioned a method of generating magnetic resonance (MR) image information of a volume with a magnetic resonance imaging (MRI) system, the method performed by at least one controller of the MRI system and may include one or more act of: generating at least a portion of a stimulated echo acquisition mode (STEAM) chemical exchange saturation transfer (CEST) sequence including first through third 90° radio frequency (RF) pulses and a first pulse train situated before the first 90° RF pulse, the first pulse train including a first number of pulses; generating at least another portion of the STEAM CEST sequence including a second pulse train situated between the second and third 90° RF pulses, the second pulse train including a second number of pulses which is less than the first number of pulses; generate end of spoil gradients; and acquiring MR information during an acquisition window which is stated at least partially after the end of spoil gradients.

In accordance with some embodiments, the first pulse train may include between 16 and 50 pulses and/or the second pulse train may include between 4 and 10 pulses. It is also envisioned that at least one of the first and second pulse trains may include sin(x)/x (SINC) pulses. It is also envisioned that a ratio of a number of pulses of the first pulse train to the second pulse train may be greater than or equal to a desired value such as an integer value, such as 4, for example. Moreover, wherein the pulses of the second pulse train may have the same duration, interval and shape as the first pulse train. The method may further include an act of reconstructing the acquired MR information to form at least one of corresponding image information and spectroscopy information.

In accordance with yet another aspect of the present system, there is envisioned a computer program stored on a computer readable memory medium, the computer program configured to generate magnetic resonance (MR) information of a volume using a magnetic resonance imaging (MRI) system having main coils, gradient coils, and radio frequency (RF) transducers, the computer program including: a program portion configured to: generate at least a portion of a stimulated echo acquisition mode (STEAM) chemical exchange saturation transfer (CEST) sequence including first through third 90° radio frequency (RF) pulses and a first pulse train situated before the first 90° RF pulse, the first pulse train including a first number of pulses; generate at least another portion of the STEAM CEST sequence including a second pulse train situated between the second and third 90° RF pulses, the second pulse train including a second number of pulses which is less than the first number of pulses; generate end of spoil gradients (116-x); and acquire MR information during an acquisition window which is started at least partially after the end of spoil gradients.

It is also envisioned that the first pulse train may include between 16 and 50 pulses and/or the second pulse train may include between 4 and 10 pulses. Further, at least one of the first and second pulse trains may include SINC pulses. Moreover, a ratio of a number of pulses of the first pulse train to the second pulse train is greater than or equal to a desired value such as an integer value, such as 4, for example. Further, the pulses of the second pulse train have the same duration, interval and shape as the first pulse train. It is further envisioned that the program portion may be further configured to reconstruct the acquired MR information to form at least one of corresponding image information and spectroscopy information.

The invention is explained in further detail, and by way of example, with reference to the accompanying drawings wherein:

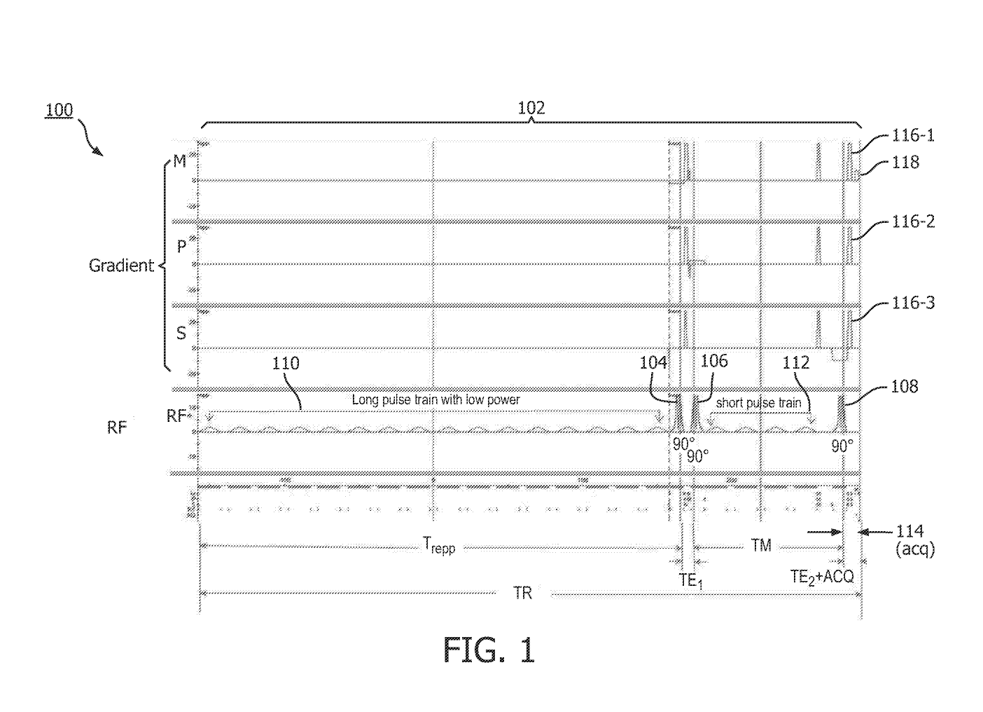

FIG. 1 is a graph of a pulse sequence generated in accordance with embodiments of the present system;

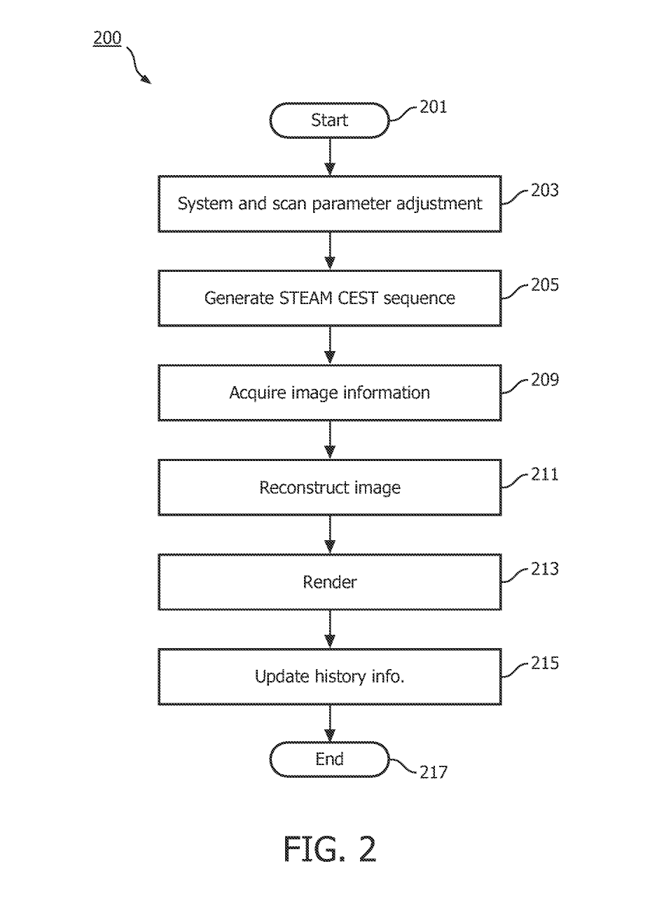

FIG. 2 is a flow diagram that illustrates a process performed by an MRI system in accordance with embodiments of the present system;

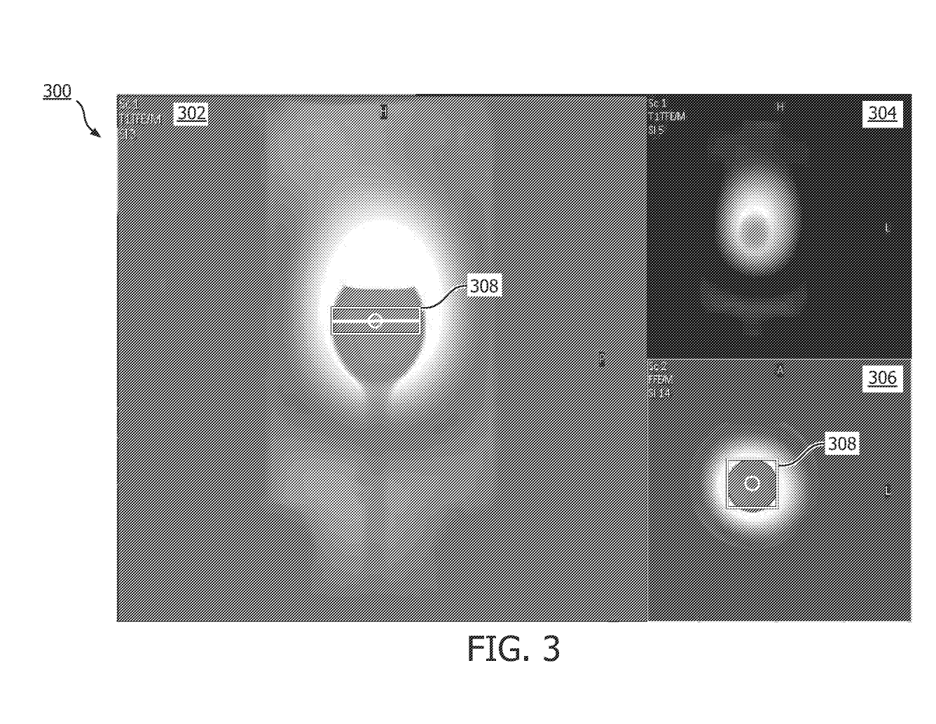

FIG. 3 is a graph which shows a three-directional structure of a phantom acquired using MRI imaging methods in accordance with embodiments of the present system;

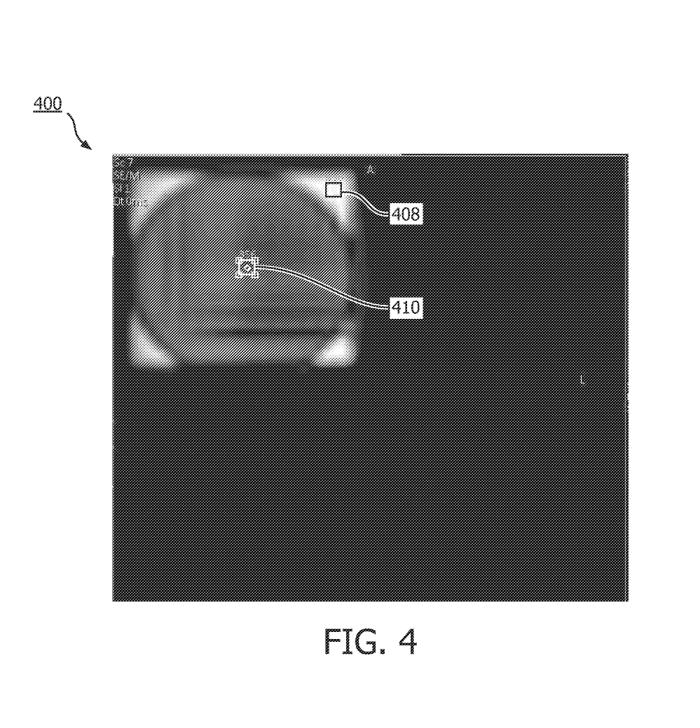

FIG. 4 is a graph which shows a first imaging of STEAM CEST scan acquired using MRI imaging methods in accordance with embodiments of the present system;

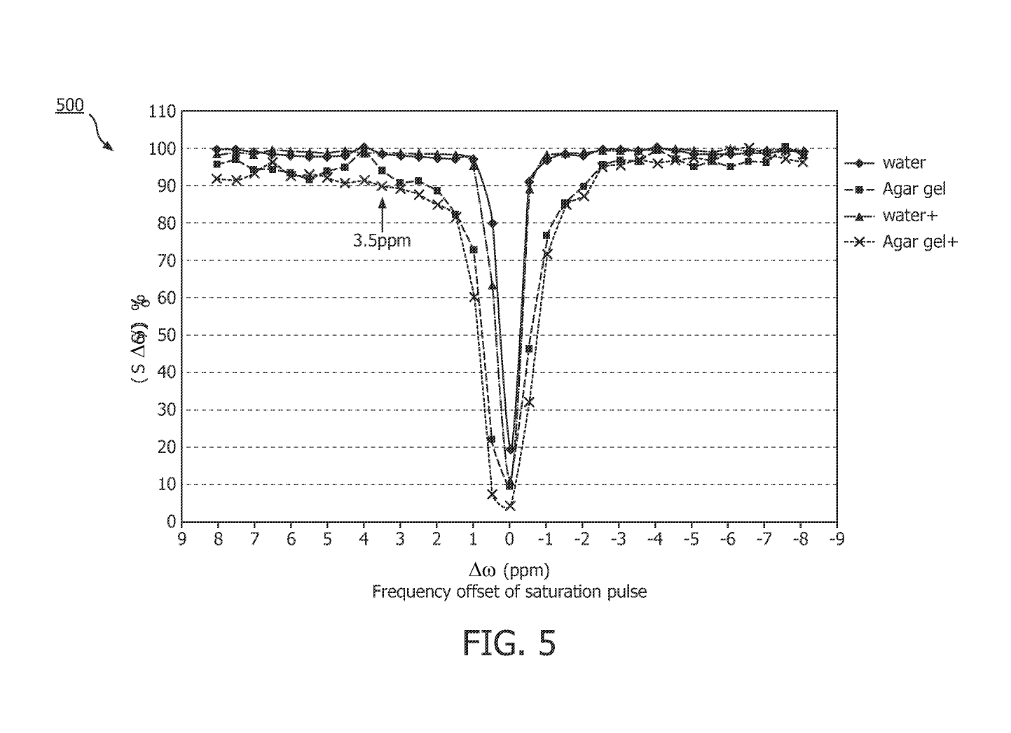

FIG. 5 shows a graph of z-spectra of two different ROIs of two STEAM CEST MRI scans obtained in accordance with embodiments of the present system;

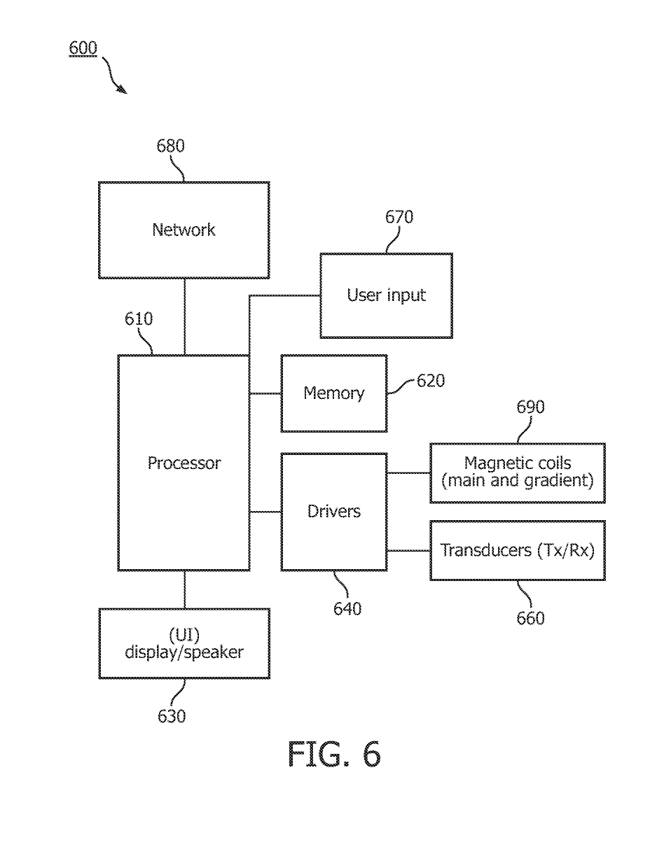

FIG. 6 shows a portion of a system in accordance with embodiments of the present system.

The following are descriptions of illustrative embodiments that when taken in conjunction with the following drawings will demonstrate the above noted features and advantages, as well as further ones. In the following description, for purposes of explanation rather than limitation, illustrative details are set forth such as architecture, interfaces, techniques, element attributes, etc. However, it will be apparent to those of ordinary skill in the art that other embodiments that depart from these details would still be understood to be within the scope of the appended claims. Moreover, for the purpose of clarity, detailed descriptions of well known devices, circuits, tools, techniques and methods are omitted so as not to obscure the description of the present system. It should be expressly understood that the drawings are included for illustrative purposes and do not represent the entire scope of the present system. In the accompanying drawings, like reference numbers in different drawings may designate similar elements.

FIG. 1 is a graph 100 of a pulse sequence 102 generated in accordance with embodiments of the present system. The pulse sequence 102 may include a STEAM CEST MRI pulse sequence and may be generated and/or output by an MRI system, or portions thereof, operating in accordance with embodiments of the present system. The sequence 102 may include first through third 90° radio frequency (RF) pulses 104, 106, and 108, respectively, which may be operative with gradients of different directions such as a measure gradient M, a phase-encoding gradient P, and a slice-select gradient S to select the signal(s) of a desired volume-of-interest (VOI), all signals from outside of VOI may be de-phased by spoil gradients, so that a field-of-view (FOV) can be reduced to the same size of the VOI if necessary or desired. The first through the third 90° RF pulses (e.g., 104, 106, and 108, respectively) may be any slice-selected excitation pulse used in a normal clinical MRI system, the pulse width (duration) for these pulses is normally from 1 milliseconds (ms) to 10 ms depending on a B₁ value of a transmit coil of the system. For example, a B₁ value of normal transmit coil can be from 10 μT to 20 μT for a human MRI system. For example, a pulse shape of at least one of the 90° RF pulses shown in FIG. 1 is an 8.8 ms Philips™ sharp pulse. After the pulses are selected, then the strengths of M, P, and/or S gradients can be determined in accordance with an excitation bandwidth of those 90° pulses and a slice thickness. In embodiments of the present system, one or more of first through third 90° RF pulses 104, 106, 108, respectively, may each be formed using pulses with a duration of 8.8 ms, 4.7 kHz bandwidth Philips™ sharp pulse waveform or the like. One or more of the first through third 90° RF pulses 104, 106, 108, respectively, may have a B₁ value of 15 μT for a typical transmitter/receiver (TR) coil operating at 7 T. However, in other embodiments the pulse shape/duration may differ as long as the sequence includes a STEAM sequence (e.g., three 90 degree pulses to select a VOI).

The pulse sequence 102 may further include at least two RF saturation composite pulses one or more of which may have a B₁ of about 2 μT. For example, in some embodiments, the at least two RF saturation pulses may include a first saturation pulse train 110 situated before the first 90° RF pulse 104 and a second saturation pulse train 112 situated after the after the second 90° RF pulse 106. The second saturation pulse train 112 may be situated within a TM period (e.g., a time delay period between the second and third 90 degree pulses).

The first saturation pulse train 110 may be referred to as a long pulse train and may include a series of 15 ms duration SINC pulses (or the like). These pulses may have a 5 ms interval between them, if desired. However, other intervals such as from 1 to 10 ms, etc. may also be used. The intervals may further be set to allow for an RF amplifier to relax as may be desired. The first saturation pulse train 110 may have a pulse train length which is between 16 and 50 pulses depending on the scan time requirement and a specific absorption rate (SAR) limitation. The SAR limitation may be set in accordance with SAR requirements as may be set by the FDA for patient safety. For example, a SAR of 4 W/kg averaged over the whole body for any 15-minute period, 3 W/kg averaged over the head for any 10-minute period; or 8 W/kg in any gram of tissue in the extremities for any period of 5 minutes, may be set. Accordingly, if the pulse train length increases, the repeat time of the sequence (TR) also increases, so it is a balance selection of scan time and pulse train length. For example, in some embodiments the first saturation pulse train 110 may include a series of 16 pulses.

The second saturation pulse train 112 may be referred to as a short pulse train and may include a series of pulses each pulse having the same duration, interval, and/or shape as pulses of the first saturation pulse train 110. However, the second pulse train length may be between 4 and 10 pulses. For example, in some embodiments, the second saturation pulse train 112 may include a series of 4 pulses. It is also envisioned that in some embodiments, the number of pulses of the second saturation pulse train 112 may be portion of the number of pulses of the first saturation pulse train 110. With regard to a TM period, this period is preferably not too long (e.g., it should be <200 ms), otherwise signal decay may be excessive, and the contrast of image will likely change, so the length of the second pulse train is limited. The frequency of the first and second saturation pulse trains 110 and 112, respectively, may, for example, be set at certain offsets such as +3.5 ppm, 0.0 ppm (where ppm is Parts Per Million), and −3.5 ppm for magnetization transfer ratio (MTR) imaging, or may be swept from 8.0 ppm to −8.0 ppm to obtain a z-spectrum, if desired. The sequence will run once at the starting with a frequency offset point to obtain an MRI image, and then the frequency of both saturation pulse trains (110 and 112) will be set to the next frequency offset point, and the scan may repeat to obtain a series of dynamic image information including images, from this image information (e.g., these images) the MTR or z-spectrum may be calculated.

A data acquisition window (ACQ) 114 may be situated after the three spoil gradients 116-x, which help to dephase the signals from outside of the VOI, and may be operative with a measurement gradient (read gradient) which is (turned) on or off to obtain desired echo information suitable to at least partially reconstruct an image, obtain spectrographic information, and/or to generate or otherwise obtain other information as may be desired. For example, the data acquisition window (ACQ) 114 may be situated after the spoil gradients and may be operative with a measurement gradient which is (turned) on to obtain information suitable for imaging scans or the like. Similarly, the data acquisition window (ACQ) 114 may be situated after the spoil gradients and may be operative with a measurement gradient which is (turned) off to obtain information suitable for spectroscopy scans or the like. To reduce scan times, embodiments of the present system may employ various techniques to process information such as multi-echo acquisition and/or parallel reconstruction techniques such as a sensitivity encoding (SENSE) technique.

Various pulse sequences such as STEAM CEST sequences in accordance with embodiments of the present system may be generated and/or output using any suitable imaging system such as a 7.0 T Philips Achieva™ imaging system and/or the like. Moreover, it is envisioned that the STEAM CEST sequences in accordance with embodiments of the present system may be generated and/or output by other MRI systems at any applicable field strength (from 1.5 T to 9.4 T) with minor changes.

FIG. 2 is a flow diagram that illustrates a process 200 performed by an MRI system in accordance with embodiments of the present system. The process 200 may be performed using one or more computers communicating over a network and may obtain information and/or store information using one or more memories which may be local and/or remote from each other. The process 200 can include one of more of the following acts. Further, one or more of these acts may be combined and/or separated into sub-acts, if desired. In operation, the process may start during act 201 and then proceed to act 203. Further, one or more of the acts of process 200 may be performed sequentially or in parallel with one or more other acts of the process 200.

During act 203, the process may perform a system and scan parameter adjustment process where, for example, the process may generate/output a STEAM CEST Sequence. The three 90° RF pulses of STEAM CEST sequence may be selected only from signals from the VOI, while all spoil gradients may be generated to attenuate or entirely remove unwanted signals from outside of the VOL Accordingly, the process may generate two saturation pulse trains (e.g., 110, 112) for generating a CEST effect, and may generate three 90° RF pulses (STEAM) for VOI selection. These signals may be overlapped in the time domain.

The process may further perform system adjustment such as localized high order shimming, and scan parameter adjustment such as determining the center frequency, right receive/transmit gains. For a typical CEST MRI, a B₀ field mapping may be acquired for data processing to correct z-spectra shift (see, R3, R5). However, for STEAM CEST MRI, since the signal is only from VOI where the B₀ field is relative uniform after the localized high order shimming, this correction may not be necessary, and the scan time may be reduced because of this. After completing act 203, the process may continue to act 205.

During act 205, the process may generate and/or output at least a portion of the STEAM CEST sequence generated in accordance with embodiments of the present system. Accordingly, the STEAM CEST sequence may be similar to the sequence 100 of FIG. 1 and/or portions thereof and may be operative to select only signals of a volume of interest (VOI) for imaging, so that a scan matrix may be reduced and the CEST saturation may be more effective. Further, the process may generate and/or output an additional saturation pulse train during a TM period within the STEAM pulse sequence. This pulse train may be similar to the short pulse train (e.g., 112) discussed elsewhere. This additional saturation pulse train may be operative to significantly improve MTR. After completing act 205, the process may continue to act 209.

During act 209, the process may perform an image acquisition process. The image acquisition process will be performed during an acquisition (ACQ) window. The acquisition process may obtain information related to the VOI such as k-space information. If an imaging scan is desired, a measurement gradient will be turned on. However, if a spectroscopy scan is desired, the gradient may be turned off. This image acquisition process may include any suitable image acquisition process such as signal pre-amplification and analog-to-digital (ADC) signal conversion. After completing act 209, the process may continue to act 211.

During act 211, the process may reconstruct an image (if it is determined that an imaging scan is desired) or a graph (if it is determined that a spectroscopy scan is desired) using at least part of the acquired information such as the k-space information. Accordingly, the process may form image information which is based at least in part on the reconstructed k-space information, if it is determined that an imaging scan is desired, or may form spectroscopy graph information which is based at least in part on the reconstructed k-space information, if it is determined that a spectroscopy scan is desired. The process may employ any suitable reconstruction methods such as noise reduction, Fast Fourier Transform (FFT) and/or signal amplitude analysis. After completing act 211, the process may continue to act 213.

During act 213, the process may render an image based upon the image information, if it is determined that an imaging scan is desired, or may render a spectroscopic graph based upon at least in part on the spectroscopy scan information, if it is determined that a spectroscopy scan is desired. The process may render the image information and/or spectroscopic graph information in a window and/or may provide a user interface (UI) with which a user may interact with the process to enter information and/or commends. The process may further provide a user with a menu with which a user may select menu items, if desired. After completing act 213, the process may continue to act 215.

During act 215, the process may update history information in accordance with information generated and/or obtained by the process. For example, the process may store the generated image information, spectroscopy scan information, k-space information, data information, user name information, scanned object name information (e.g., patient name information), day, data, time, scan parameters, etc., in a memory of the system for later use. After completing act 215, the process may continue to act 217 where it ends.

### Exemplary Test Results

To test the efficiency of sequences in accordance with embodiments of the present system, a two-compartment phantom was used to obtain exemplary test results using scans performed using a 7.0 T Philips™ Achieva™ imaging system. The two-compartment phantom was formed from a half-gallon cylindrical bottle which defined a cavity. The cavity may include an outer compartment filled with a water solution (e.g., 1.2 g/L NiCl₂) and an inner compartment (e.g., a 50 mL volumetric flask) filled with an agar gel (e.g., 4% dry weight) and placed in the middle of the inner compartment of the bottle.

FIG. 3 is a graph 300 which shows a three-directional structure of a phantom acquired using MRI imaging methods in accordance with embodiments of the present system. The graph 300 was reconstructed in accordance with information (e.g., k-space information, etc.) obtained using a Fast Field Echo (FFE) scan employing a Transmit/Receive (TR) knee-coil (the coil) operating in accordance with embodiments of the present system. The graph 300 includes first through third windows 302, 304, and 306, respectively, each of which includes a gradient echo MRI image of the phantom taken from a different direction of three directions. More particularly, a sagittal image is shown in the first window 302, a coronal image is shown in the second window 304, and a transverse image is shown in the third window 306. A selected VOI is indicated by boxes 308 in the first and third windows 302 and 306, respectively, which is used for STEAM CEST scan later. In the current embodiments, the size of VOI is 42 mm (AP)×43 mm (RL)×12 mm (FH) where AP refers to anterior to posterior, RL refers to right to left, and FH refers to feet to head. Inside the VOI, the four cornels in transverse imaging are water solution which will be used as reference for comparison of a CEST effect since there should be no CEST effect for water. The scan parameters for a STEAM CEST scan performed in accordance with embodiments of the present system are listed below in Table 1.

TABLE 1
STEAM CEST Parameters

FOV = 100 mm × 100 mm
Scan matrix = 64 × 64
TR/TE/TM = 1000 ms/18 ms/100 ms
16 pulses for the long composite pulse (total duration 315 ms)
4 pulses for the short composite pulse (total duration 75 ms)

Frequency offset of the saturation pulses is changed for each scan. The STEAM CEST sequence was repeated 33 times (however, other numbers are also envisioned), for each scan, only the frequency offset of the saturation pulse trains (e.g., the long and short train 110 and 112, respectively) was changed, e.g., swept from 8.0 ppm to −8.0 ppm, however, all other pulses keep the same frequency offset during each scan of the 33 scans. Thus, for each of the 33 scans, the frequency offset of the saturation pulse trains (e.g., 110 and 112) was swept from 8.0 ppm to −8.0 ppm with an interval of 0.5 ppm for each imaging point for a total of 33 dynamic scans and a total scan time is 35 minutes for a z-spectrum swept. The scan was repeated with the short pulse train off in order to evaluate the improvement of the addition saturation pulse. Before the STEAM CEST scan, the high-order shimming was optimized/applied on the selected VOL

FIG. 4 is a graph 400 which shows a first imaging of STEAM CEST scan acquired using MRI imaging methods in accordance with embodiments of the present system. To obtain graph 400, a frequency offset was set at 8.0 ppm. To obtain a z-spectrum in FIG. 5, an average signal intensity of a region-of-interest (ROI) 408, 410 from the 33 images was employed. The ROI 408 was selected for a water signal and the ROI 410 was selected for an agar gel signal. Each of the ROIs 408 and 410 is sized at 22 mm².

FIG. 5 shows a graph 500 of z-spectra of two ROIs of two STEAM CEST MRI scans obtained in accordance with embodiments of the present system, where the y-axis is the ratio of signal intensity with the long saturation pulse train only, with both the long and short pulse trains to without any saturation pulse train (where the image without any saturation pulse train was not acquired here, instead the maximum signal intensity of 33 images is used in the calculation, which is a good approximation to the signal acquired without saturation pulses, since the unsaturated signal is about the same amplitude as the signal acquired when the offset frequency of saturation pulse is larger, such as around −8.0 ppm), and the x-axis is the frequency offset of the saturation pulses. The ROIs of water and agar gel. Scans obtained with the short saturation pulse train (112 of FIG. 1) toggled ON are indicated as “water+” and “Agar gel+”, and with the short composite pulse OFF indicated as “water” and “Agar gel”. All z-spectra (e.g., for the water and agar gel) indicate that the highest saturation is achieved at 0.0 ppm, which means no B₀ correction is required for STEAM CEST MRI scans. For agar gel, on the left side of the graph 500 (8.0 ppm to 0.0 ppm area), a greater amount of saturation is obtained with the short saturation pulse train (e.g., 112) ON comparing to the saturation with the short saturation pulse train (e.g., 112) OFF. On the right side of the graph 500 (0.0 ppm to −8.0 ppm), there is only minor change with the short saturation pulse train toggled ON/OFF. For water signal, the additional short saturation pulse train within STEAM made almost no change for the water z-spectrum except higher saturation at 0.0 ppm.

In accordance with embodiments of the present system, the CEST effect can be defined as:

MTR_{asym}=(S[−3.5]−S[+3.5])/S₀, Eq. (2)

where, S₀ is a signal intensity without any saturation pulse, and S[−3.5], S[+3.5] is a signal intensity when the frequency of the saturation pulse is set at −3.5 ppm or 3.5 ppm, respectively. For agar gel, MTRₐₛₘ increased from the 2.4% to 6.8% with the additional saturation pulse train 112 during TM period. For water, MTR_{asym} was substantially equal to or about 0% for both scans. During the scans, the short saturation pulse train may be toggled ON/OFF. However, the long saturation pulse train is always on for both scans.

FIG. 6 shows a portion of a system 600 (e.g., peer, server, etc.) in accordance with embodiments of the present system. For example, a portion of the present system 600 may include a processor 610 (e.g., a controller) operationally coupled to a memory 620, a user interface 630, drivers 640, RF transducers 660, magnetic coils 690, and a user input device 670. The memory 620 may be any type of device for storing application information as well as other information related to the described operation. The application information and other information are received by the processor 610 for configuring (e.g., programming) the processor 610 to perform operation acts in accordance with the present system. The processor 610 so configured becomes a special purpose machine particularly suited for performing in accordance with embodiments of the present system.

The magnetic coils 690 may include main magnet coils (e.g., main magnets, DC coils, etc.), and the gradient coils (e.g., x-, y-, and z-gradient coils, gradient slice select, gradient phase encoding, etc.) and may be controlled to emit a main magnetic field and/or gradient fields in a desired direction and/or strength in accordance with embodiments of the present system.

The operation acts may include configuring an MRI system 600 by, for example, the processor 620 controlling the drivers 640 to generate main, gradient, and/or RF signals for output by the main magnet coils, gradient coils, and/or RF transducers, respectively. Thereafter, echo information may be received by receivers of the RF transducers 660 and provided to the processor 610 for further processing and/or reconstruction into image information in accordance with embodiments of the present system. This information may include navigator information. The processor 610 may control the drivers 649 to provide power to the magnetic coils 690 so that a desired magnetic field is emitted at a desired time. The RF transducers 660 may be controlled to transmit RF pulses at the test subject and/or to receive information such as MRI (echo) information therefrom. A reconstructor may process detected information such as echo information and transform the detected echo information into content in accordance with methods of embodiments of the present system. This content may include image information (e.g., still or video images, video information, etc.), information, and/or graphs that can be rendered on, for example, the user interface (UI) 630 such as a display, a speaker, etc. Further, the content may then be stored in a memory of the system such as the memory 620 for later use and/or processing in accordance with embodiments of the present system. Thus, operation acts may include requesting, providing, and/or rendering of content such as, for example, reconstructed image information may be obtained from the echo information and be navigator corrected. The processor 610 may render the content such as video information on the UI 630 such as on a display of the system. The reconstructor may obtain image information (e.g., raw, etc.), navigator information, prep-phase information, etc., and may reconstruct the image information in accordance with the navigator information and/prep phase information using any suitable image processing method or methods (e.g., digital signal processing (DSP), algorithms, etc., so as to obtain content. For example, the reconstructor may calculate and correct gradient delays in reconstruction in real time.

The sensors may include suitable sensors to provide desired feedback information to the processor 610 for further processing.

The user input 670 may include a keyboard, a mouse, a trackball, or other device, such as a touch-sensitive display, which may be stand alone or be a part of a system, such as part of a personal computer, a personal digital assistant (PDA), a mobile phone, a monitor, a smart- or dumb-terminal or other device for communicating with the processor 610 via any operable link. The user input device 670 may be operable for interacting with the processor 610 including enabling interaction within a UI as described herein. Clearly, the processor 610, the memory 620, display 630, and/or user input device 670 may all or partly be a portion of a computer system or other device such as a client and/or server.

The methods of the present system are particularly suited to be carried out by a computer software program, such program containing modules corresponding to one or more of the individual steps or acts described and/or envisioned by the present system. Such program may of course be embodied in a computer-readable medium, such as an integrated chip, a peripheral device or memory, such as the memory 620 or other memory coupled to the processor 610.

The program and/or program portions contained in the memory 620 configure the processor 610 to implement the methods, operational acts, and functions disclosed herein. The memories may be distributed, for example between the clients and/or servers, or local, and the processor 610, where additional processors may be provided, may also be distributed or may be singular. The memories may be implemented as electrical, magnetic or optical memory, or any combination of these or other types of storage devices. Moreover, the term “memory” should be construed broadly enough to encompass any information able to be read from or written to an address in an addressable space accessible by the processor 610. With this definition, information accessible through a network is still within the memory, for instance, because the processor 610 may retrieve the information from the network for operation in accordance with the present system.

The processor 610 is operable for providing control signals and/or performing operations in response to input signals from the user input device 670 as well as in response to other devices of a network and executing instructions stored in the memory 620. For example, the processors 610 may obtain feedback information from the sensors 640, may determine whether there is a mechanical resonance. The processor 610 may include one or more of a microprocessor, an application-specific or general-use integrated circuit(s), a logic device, etc. Further, the processor 610 may be a dedicated processor for performing in accordance with the present system or may be a general-purpose processor wherein only one of many functions operates for performing in accordance with the present system. The processor 610 may operate utilizing a program portion, multiple program segments, or may be a hardware device utilizing a dedicated or multi-purpose integrated circuit.

Embodiments of the present system may be have provided stable and reproducible MRI image information and may be compatible with use in conventional MRI systems such as PHILIPS™ Achieva™ and Ingenia™ imaging systems and the like.

Embodiments of the present system employ a technique which may include one or more of the following acts: (1) generating a stimulated echo acquisition mode (STEAM) sequence (see, R6) to select only signal of the volume of interest (VOI) for imaging, so the scan matrix may be reduced and/or an RF saturation pulse works more efficiently on the VOI; (2) generating an additional saturation pulse train during TM period to significantly improve MTR; and (3) performing localized high-order shimming to improve the uniformity of a B₀ field so that B₀ field mapping for typical CEST MRI is not necessary. Further, in accordance with embodiments of the present system, the sequence(s) discussed herein may also be employed for CEST spectroscopy and the like.

Further variations of the present system would readily occur to a person of ordinary skill in the art and are encompassed by the following claims. Through operation of the present system, a virtual environment solicitation is provided to a user to enable simple immersion into a virtual environment and its objects.

Finally, the above-discussion is intended to be merely illustrative of the present system and should not be construed as limiting the appended claims to any particular embodiment or group of embodiments. Thus, while the present system has been described with reference to exemplary embodiments, it should also be appreciated that numerous modifications and alternative embodiments may be devised by those having ordinary skill in the art without departing from the broader and intended spirit and scope of the present system as set forth in the claims that follow. In addition, the section headings included herein are intended to facilitate a review but are not intended to limit the scope of the present system. Accordingly, the specification and drawings are to be regarded in an illustrative manner and are not intended to limit the scope of the appended claims.

The section headings included herein are intended to facilitate a review but are not intended to limit the scope of the present system. Accordingly, the specification and drawings are to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

1. A magnetic resonance imaging (MRI) system for acquiring magnetic resonance (MR) information of a volume, the MRI system comprising:
at least one controller configured to:
generate at least a portion of a stimulated echo acquisition mode (STEAM) chemical exchange saturation transfer (CEST) sequence comprising first through third 90 degree radio frequency (RF) pulses, and a first pulse train situated before the first 90 degree RF pulse, the first pulse train comprising a first number of pulses;
generate at least another portion of the STEAM CEST sequence comprising a second pulse train situated between the second and third 90 degree RF pulses, the second pulse train comprising a second number of pulses which is less than the first number of pulses;
generate end of spoil gradients; and
acquire MR information during an acquisition window which is started at least partially after the end of spoil gradients.

2. The MRI system of claim 1, wherein the first pulse train comprises between 16 and 50 pulses.

3. The MRI system of claim 1, wherein the second pulse train comprises between 4 and 10 pulses.

4. The MRI system of claim 1, wherein at least one of the first and second pulse trains comprises sin(x)/x (SINC) pulses.

5. The MRI system of claim 1, wherein the pulses of the second pulse train have the same duration, interval and shape for each individual pulse within the pulse train as the first pulse train.

6. The MRI system of claim 1, wherein the controller is further configured to reconstruct the acquired MR information from at least one of corresponding image information and spectroscopy information.

7. A method of generating magnetic resonance (MR) image information of a volume with a magnetic resonance imaging (MRI) system, the method performed by at least one controller of the MRI system and comprising acts of:
generating at least a portion of a stimulated echo acquisition mode (STEAM) chemical exchange saturation transfer (CEST) sequence comprising first through third 90 degree radio frequency (RF) pulses, and a first pulse train situated before the first 90 degree RF pulse, the first pulse train comprising a first number of pulses;
generating at least another portion of the STEAM CEST sequence comprising a second pulse train situated between the second and third 90 degree RF pulses, the second pulse train comprising a second number of pulses which is less than the first number of pulses; and
acquiring MR information during an acquisition window which is started at least partially after the start of the third 90 degree RF pulse.

8. The method of claim 7, wherein the first pulse train comprises between 16 and 50 pulses.

9. The method of claim 7, wherein the second pulse train comprises between 4 and 10 pulses.

10. The method of claim 7, wherein at least one of the first and second pulse trains comprises sin(x)/x (SINC) pulses.

11. The method of claim 7, wherein the pulses of the second pulse train have the same duration, interval and shape for each individual pulse within the pulse train as the first pulse train.

12. The method of claim 7, further comprising an act of reconstructing the acquired MR information to form at least one of corresponding image information and spectroscopy information.

13. A non-transitory computer readable medium comprising a computer program, the computer program comprising instructions which, when executed by a processor, configure the processor to generate magnetic resonance (MR) information of a volume using a magnetic resonance imaging (MRI) system having main coils, gradient coils, and radio frequency (RF) transducers the computer program comprising a program portion configured to:
generate at least a portion of a stimulated echo acquisition mode (STEAM) chemical exchange saturation transfer (CEST) sequence comprising first through third 90 degree radio frequency (RF) pulses, and a first pulse train situated before the first 90 degree RF pulse, the first pulse train comprising a first number of pulses
generate at least another portion of the STEAM CEST sequence comprising a second pulse train situated between the second and third 90 degree RF pulses, the second pulse train comprising a second number of pulses which is less than the first number of pulses; and
acquire MR information during an acquisition window which is started at least partially after the start of the third 90 degree RF pulse.

14. The non-transitory computer readable medium system of claim 13, wherein the first pulse train comprises between 16 and 50 pulses.

15. The non-transitory computer readable medium system of claim 13, wherein the second pulse train comprises between 4 and 10 pulses.
